(19) United States
(12) Patent Application Publication
(10) Pub. No.: US 2019/0131197 A1
(43) Pub. Date: May 2, 2019

(54) QUAD FLAT NO-LEAD PACKAGE

(71) Applicants: STMicroelectronics S.r.l., Agrate Brianza (MB) (IT); STMicroelectronics (Rousset) SAS, Rousset (FR)

(72) Inventors: Felice Versiglia, Aix en Provence (FR); Antoine Pavlin, Puyricard (FR); Claudio Tagliapietra, Milan (IT)

(21) Appl. No.: 16/169,700

(22) Filed: Oct. 24, 2018

(30) Foreign Application Priority Data
Oct. 26, 2017 (FR) 1760104

(51) Int. Cl. H01L 23/31; H01L 23/495; H01L 23/00

(52) U.S. Cl. CPC H01L 23/3107; H01L 23/49548; H01L 24/73; H01L 24/32; H01L 24/48; H01L 23/49537

(57) ABSTRACT

An electronic circuit can include a semiconductor chip having a thickness smaller than 160 μm and a package with flush contacts having the chip encapsulated therein. In some cases, the chip takes up more than twenty-five percent of the surface area of the package. The package can be a quad flat no-lead (QFN) package.

### CROSS-REFERENCE TO RELATED APPLICATIONS

This application claims priority to French Patent Application No. 1760104, filed on Oct. 26, 2017, which application is hereby incorporated herein by reference.

### TECHNICAL FIELD

The present disclosure generally relates to electronic circuits and, in specific embodiments, to packaging of integrated circuit chips.

### BACKGROUND

Integrated circuits are generally encapsulated in packages. Different categories of packages are known, which mainly depend on the technique used to connect contacts of the chip made of semiconductor material to terminals (pads, tabs, etc.) of connection to other circuits and on the technique used to assemble the electronic circuits (packaged integrated circuit) on a support (printed circuit board or the like).

Three large families of packages can mainly be distinguished. DIP (Dual Inline Package) or QFP (Quad Flat Package) packages, comprising a lead frame, where the chip is placed on a central portion of a lead frame comprising pins coming out of the package to be soldered to the printed circuit board. BGA (Ball Grid Array) packages having solder balls at their lower surface. QFN (Quad Flat No-lead) packages with no lead frame, comprising contacts flush with the package to be soldered to the printed circuit board.

The present disclosure applies to packages from this last QFN family.

### SUMMARY

An embodiment decreases all or part of the disadvantages of packages with no lead frame.

An embodiment provides a solution particularly capable of improving the thermal cycling behavior of a circuit in a QFN package.

Thus, an embodiment provides an electronic circuit comprising a semiconductor chip having a thickness smaller than 160 μm and a package with flush contacts having the chip encapsulated therein, wherein the chip takes up more than twenty-five percent of the surface area of the package.

According to an embodiment, conductive wires connect, inside of the package, contacts at the upper surface of the chip to the upper surface of at least some of the flush contacts.

According to an embodiment, the largest linear dimension of the chip represents at least fifty percent of the largest linear dimension of the package.

According to an embodiment, the largest linear dimension of the chip represents between fifty and seventy percent of the largest linear dimension of the package.

According to an embodiment, the surface area of the chip represents between twenty-five and fifty percent of the surface area of the package.

According to an embodiment, the chip and the package have rectangular major surfaces, each edge of the chip representing between fifty and seventy percent of the edge of the package to which it is parallel.

According to an embodiment, the chip has a thickness smaller than 110 μm, preferably smaller than 70 μm.

According to an embodiment, the package is made of epoxy resin.

According to an embodiment, the package is of the type comprising no lead frame.

According to an embodiment, the package is of QFN type.

According to an embodiment, the circuit comprises a first flush contact approximately at the center of the lower surface of the package and a plurality of second flush contacts distributed at the periphery of the lower surface of the package. The second contacts are flush with the lower surface and with the periphery of the package.

According to an embodiment, the first contact, receives, at its upper surface, the lower surface of the chip.

According to an embodiment, a welding or glue joint is present between the chip and the first contact.

According to an embodiment, the surface area of the first contact is larger than the surface area of the chip.

According to an embodiment, the first contact takes up more than sixty percent of the surface area of the lower surface of the package.

According to an embodiment, the second contacts receive, at their upper surface, conductive wires of connection to contacting areas at the upper surface of the chip.

According to an embodiment, the upper surface of the package comprises no contacts.

An embodiment provides an integrated circuit adapted to an electronic circuit such as described.

The foregoing and other features and advantages will be discussed in detail in the following non-limiting description of specific embodiments in connection with the accompanying drawings.

### BRIEF DESCRIPTION OF THE DRAWINGS

FIGS. 1A and 1B are respective top and bottom views of an embodiment of an electronic circuit in a QFN package;

FIG. 2 is a cross-section view of an electronic circuit in a usual QFN package assembled on a printed circuit board;

FIG. 3 is a simplified cross-section view of an embodiment of an electronic circuit in a QFN package; and

FIG. 4 is a graph showing experimental results showing the number of cycles as a function of die/package area ratio at a number of thicknesses.

### DETAILED DESCRIPTION OF ILLUSTRATIVE EMBODIMENTS

The same elements have been designated with the same reference numerals in the different drawings.

For clarity, only those steps and elements which are useful to the understanding of the embodiments which will be described have been shown and will be detailed. In particular, the steps of assembly in packages and of assembly of the packages on a printed circuit board have only been detailed for the needs of the present disclosure, the other manufacturing and assembly details being compatible with usual QFN package manufacturing and use techniques. Similarly, the manufacturing of the semiconductor chips has not been detailed more than necessary to explain the described embodiments, such a manufacturing using techniques usual per se. Further, the electronic function(s) fulfilled by the electronic circuit have not been detailed, the described embodiments being compatible with any usual function of an electronic circuit.

Unless otherwise specified, when reference is made to two elements connected together, this means directly connected with no intermediate element other than conductors, and when reference is made to two elements coupled together, this means that the two elements may be directly coupled (connected) or coupled via one or a plurality of other elements. Further, when reference is made of terms qualifying an absolute position, such as “upper”, “lower”, etc., it is referred, unless otherwise mentioned, to the orientation of the drawings.

In the following description, when reference is made to terms “approximately”, “about”, and “in the order of”, this means to within 10%, preferably to within 5%.

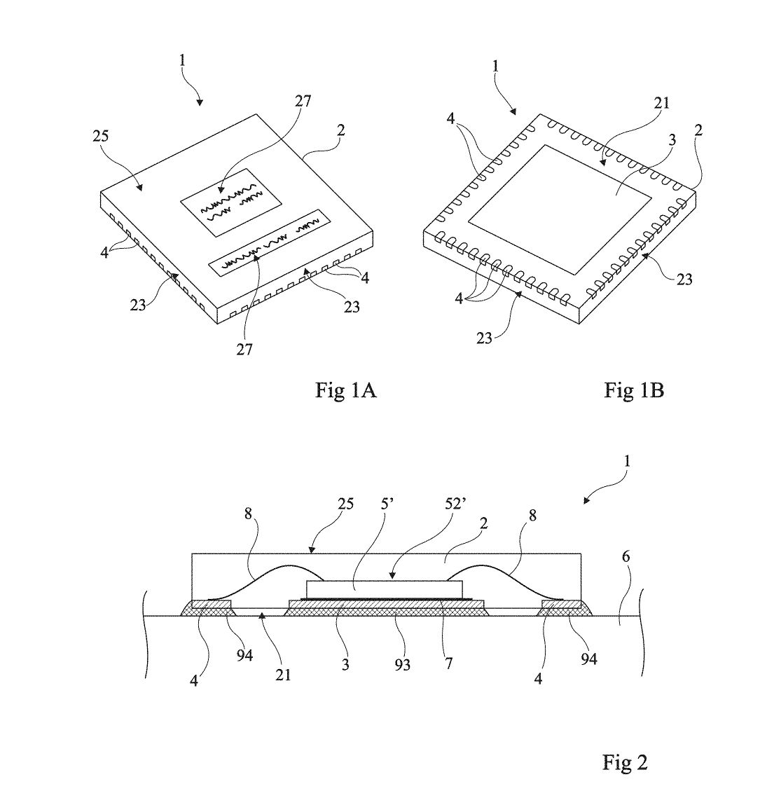

FIGS. 1A and 1B are respective top and bottom views of an embodiment of an electronic circuit 1 in a QFN package 2.

Circuit 1 comprises an integrated circuit chip made of a semiconductor material (not shown in FIGS. 1A and 1B) and a package 2 of type QFN.

A QFN package 2 is a package with no lead frame and having flush contacts. Package 2 has the shape of a rectangle or square cuboid and comprises no outgrowth from its different surfaces, which are preferably planar.

At lower surface 21 (the surface visible on the top in FIG. 1B), package 2 comprises a first, approximately central, flush contact 3, and a plurality of second peripheral flush contacts 4. Peripheral contacts 4 are flush not only with lower surface 21 but also with peripheral surface 23 of the package on the side of which they are located.

The number of peripheral contacts 4 depends on the connection need of the integrated circuit chip. Generally, contacts 4 are regularly distributed at the periphery with a same number of contacts 4 on each side.

Lower surface 21 is intended to be placed on an electronic circuit support, for example, a printed circuit board (not shown in FIGS. 1A and 1B; see board 6 in FIG. 2). Contacts 3 and 4 are intended to be soldered or welded on conductive areas of this wafer, with a solder input.

At upper surface 25 (FIG. 1A), package 2 generally comprises no conductive parts. Upper surface 25 most often bears inscriptions 27 identifying the manufacturer and/or the nature of the electronic circuit.

Package 2 is generally mainly made of epoxy resin molded around the different components.

FIG. 2 is a cross-section view of an electronic circuit 1, in a usual QFN package, assembled on a printed circuit board 6.

It comprises epoxy resin package 2 and, at lower surface 21, flush contacts 3 and 4. FIG. 2 shows the assembly of the chip, here 5′, made of a semiconductor material, by its rear or lower surface, to the upper surface (internal to package 2), of central contact 3. Chip 5′ is soldered or glued (welding or glue joint 7) at the upper surface of contact 3. Thus, the chip is linked to contact 3 sufficiently rigidly to oppose its natural thermal expansion. Second contacts 4 receive, at their upper surface, conductive wires 8 of connection to contacting areas present at upper surface 52′ of the chip.

Circuit 1 is assembled on board 6 by its lower surface 21. Contacts 3 and 4 are soldered (solders 93 and 94) to metal areas, not shown, of board 6. The destination of such metal areas, for example, for connection to ground, interconnection to other electronic circuits, connection to input-output terminals supported by board 6, etc. is usual and is not modified by the described embodiments.

This type of package is adapted to chips 5′ having a relatively small surface area, typically which corresponds to less than half the surface area of the package, and which do not heat too much. In other words, there is a reliability issue due to the thermal stress undergone by the chip. Indeed, the fact for the package to be directly soldered to printed circuit board 6 results in that the thermal stress undergone, including by board 6, impacts the chip. In a QFN package, that is, with no lead frame, the pins which generally equip a DIP or QFP package are not present to absorb expansions. In particular, in case of a heating, chip 5′ remains rigid and prevents the expansion of central contact 3. As a result, board 6 exerts a shearing effort on the welds of contact 3 and of contacts 4 with board 6, which damages the electronic circuit. This may even, in certain cases, separate the chip from contact 3.

This problem is all the more critical as the chip, and thus central contact 3, takes up a large surface area with respect to the total surface area of the package. In practice, this limits the surface area of the chip to approximately 25% of the total surface area of the package for packages submitted to strong thermal stress such as, for example, in automobile industry applications.

According to the described embodiments, it is provided to authorize a deformation of the semiconductor material chip by decreasing the thickness thereof.

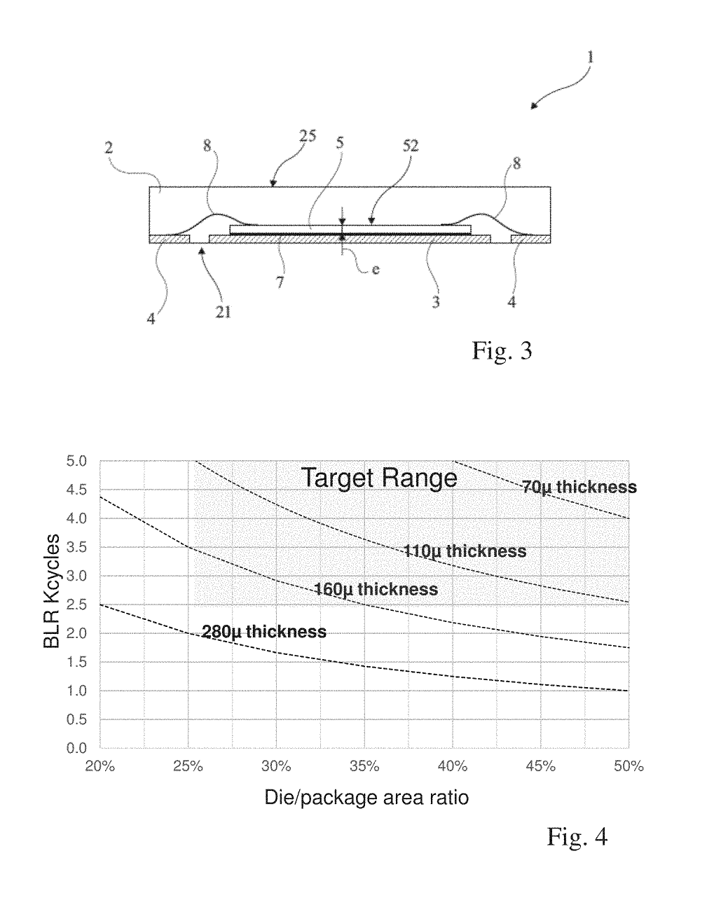

FIG. 3 is a simplified cross-section view of an embodiment of an electronic circuit in a QFN package.

It shows a package 2, preferably made of epoxy resin and, at lower surface 21 of the package, flush contacts, respectively central 3 and peripheral 4. A chip, here 5, made of semiconductor material, is assembled by its rear or lower surface, at the upper surface (internal to package 2) of central contact 3. This rear surface of chip 5 generally supports a ground plane, having the heat partly carried off therethrough. Chips 5 is soldered or glued (joint 7) to the upper surface of contact 3. Peripheral contacts 4 receive, at the upper surface, conductive wires 8 of connection to contacting areas present at upper surface 52 of chip 5. The rest, and particularly the assembly on a printed circuit board, is usual and such as described hereabove.

According to the embodiment of FIG. 3, chip 5 has a thinner thickness e than chips 5′ of usual electronic circuits in a QFN package. Chip 5 is sufficiently thin to follow the thermal deformations of the printed circuit board, which are transmitted by central contact 3 of package 2. In order for such a decrease to be sufficient to absorb several thousands of cycles, preferably at least two thousand cycles, of temperature rise up to temperatures in the range from 100 to 150 degrees, preferably in the order of 125° C., for circuits 1 where the surface area of chip 5 corresponds to more than twenty-five percent of the surface area of package 2, a thickness e of chip 5 smaller than 160 μm is provided. The thinner chip 5, the better the mechanical deformation.

The thinning is preferably performed at the level of the semiconductor wafer before it is sawn to individualize the integrated circuit chips that it comprises. Such a thinning is typically performed from the rear surface of the wafer, which has its components formed at the front surface. Thus, the described solutions preferably apply to the forming of integrated circuits having components which only take up part of the thickness of the semiconductor wafer.

According to the described embodiments, the surface area occupied by the chip is preferably comprised between twenty-five and fifty percent of the surface area of the package.

Preferably, in terms of linear dimensions, i.e., horizontal dimensions (perpendicular to the thickness), the largest linear dimension of the chip represents at least fifty percent and is preferably comprised between fifty and seventy percent of the largest linear dimension of the package.

According to an embodiment, the chip and the package have a rectangular shape or a rectangular major or main surface area. Each side or edge of the chip has a length representing of at least fifty percent, preferably a length comprised between fifty and seventy percent, of the side or edge of the package to which it is parallel.

In other words, the package is chosen as a function of the dimensions and/or surface area of the chip to respect the proportions above.

An advantage of the described embodiments is that chip 5 can follow the deformations of central contact 3, which attenuates, or even suppresses, mechanical stress on the solder joints (93 and 94 in FIG. 2) of contacts 3 and 4 with the board and on solder joint 7. This advantage is not only obtained thanks to the low thickness of the chip, but also by the relatively large surface area of the chip with respect to the package as compared to known solutions.

Another advantage is that this makes QFN packages compatible with applications, such as automobile applications, where the thermal stress is significant and/or where the surface areas of the chips correspond to more than twenty-five percent of the surface area of the package.

Another advantage is that the decrease of thickness e of the chip allows a corresponding decrease of the total thickness of package 2, and thus of circuit 1.

Preferably, chip 5 takes up a surface area corresponding to more than twenty-five percent of lower surface 21 of package 2. Preferably, central contact 3 takes up a surface area corresponding to at least fifty percent and preferably to more than sixty percent of lower surface 21 of package 2.

As a specific embodiment, an electronic circuit such as described hereabove comprises a chip 5 having a surface area in the range from approximately 10 mm² to approximately 15 mm² and having a thickness smaller than 110 μm, preferably in the order of 70 μm.

Another advantage of the described embodiments is that they require no modification of the actual packaging process, nor of the encapsulation, nor of the assembly of the circuit in a QFN package on a printed circuit board.

Embodiments are useful in a number of applications. For example, in smart power products for automotive applications it is desirable to achieve a number of board level temperature cycles in QFN packages, e.g., more than two thousand cycles (2 Kcycles). It is also desirable to have a large die inside the package, e.g., up to 50% of the package area or more.

FIG. 4 shows experimental results showing the number of BLR (board level reliability) cycles as a function of die/package area ratio for dies at a number of thicknesses. As noted above, the target for certain applications is to have at least 2500 cycles at a die/package area ratio greater than 25%. A typical thermal cycling condition for BLR is from −40° C. to +125° C. As shown in the chart, this goal can be achieved with die thicknesses of 160 μm and less. For example, it is possible to reach 4000 BLR cycles with a die/package area ratio of 50% and a die thickness of 70 μm.

Various embodiments have been described. Various alterations, modifications, and improvements will readily occur to those skilled in the art. In particular, the selection of the field emission duration may vary from one application to another. Further, the practical implementation of the described embodiments, and in particular the selection of the final thickness of and of the technique to be used to thin the semiconductor material wafer having the chips formed therein, is within the abilities of those skilled in the art by using the functional indications given hereabove.

Such alterations, modifications, and improvements are intended to be part of this disclosure, and are intended to be within the spirit and the scope of the present invention. Accordingly, the foregoing description is by way of example only and is not intended to be limiting. The present invention is limited only as defined in the following claims and the equivalents thereto.

What is claimed is:

1. An electronic device comprising:
a semiconductor chip having a thickness smaller than 160 μm; and
a package with flush contacts having the chip encapsulated therein, wherein the chip takes up more than twenty-five percent of the surface area of a major surface of the package.

2. The electronic device of claim 1, wherein the largest linear dimension of the chip represents at least fifty percent of the largest linear dimension of the package.

3. The electronic device of claim 1, wherein the largest linear dimension of the chip represents between fifty and seventy percent of the largest linear dimension of the package.

4. The electronic device of claim 1, wherein the surface area of the chip represents between twenty-five and fifty percent of the surface area of the package.

5. The electronic device of claim 1, wherein the chip and the package have rectangular surfaces, each edge of the chip representing between fifty and seventy percent of the edge of the package to which it is parallel.

6. The electronic device of claim 1, wherein conductive wires inside of the package connect contacts at an upper surface of the chip to an upper surface of at least some of the flush contacts.

7. The electronic device of claim 1, wherein the chip has a thickness smaller than 110 μm.

8. The electronic device of claim 7, wherein the chip has a thickness smaller than 70 μm.

9. The electronic device of claim 1, wherein the package is made of epoxy resin.

10. The electronic device of claim 1, wherein the package comprises no lead frame.

11. The electronic device of claim 1, wherein the package is a quad flat no-lead (QFN) package.

12. The electronic device of claim 1, comprising:
a first flush contact at a center location of a lower surface of the package; and
a plurality of second flush contacts distributed at a periphery of the lower surface of the package, the second contacts being flush with the lower surface and with a periphery of the package.

13. The electronic device of claim 12, wherein the first contact receives, at its upper surface, the lower surface of the chip.

14. The electronic device of claim 13, further comprising a welding or glue joint between the chip and the first contact.

15. The electronic device of claim 12, wherein the first contact has a surface area that is larger than a surface area of the chip.

16. The electronic device of claim 12, wherein the first contact takes up more than sixty percent of the surface area of the lower surface of the package.

17. The electronic device of claim 12, wherein the second contacts receive, at their upper surface, conductive wires of connection to contacting areas at the upper surface of the chip.

18. The electronic device of claim 1, wherein an upper surface of the package comprises no contacts.

19. An electronic device comprising:
a semiconductor chip; and
a package with flush contacts having the chip encapsulated therein;
wherein the chip takes up more than twenty-five percent of the surface area of a major surface of the package; and
wherein the electronic device is configured to withstand at least 2500 temperature cycles between temperatures of −40° C. to +125° C.

20. The electronic device of claim 19, wherein the semiconductor chip has a thickness of 160 μm or less.

21. The electronic device of claim 20, wherein the semiconductor chip has a thickness of 110 μm or less and wherein the chip takes up between twenty-five and fifty percent of the surface area of the major surface of the package.

22. The electronic device of claim 21, wherein the semiconductor chip has a thickness of 70 μm or less and wherein the chip takes up more than twenty-five percent of the surface area of the major surface of the package.

23. The electronic device of claim 22, wherein the electronic device is configured to withstand at least 4000 temperature cycles between temperatures of −40° C. to +125° C.

24. The electronic device of claim 19, further comprising:
a first flush contact at a center location of a lower surface of the package; and
a plurality of second flush contacts distributed at a periphery of the lower surface of the package, the second contacts being flush with the lower surface and with a periphery of the package.

25. The electronic device of claim 19, wherein the largest linear dimension of the chip represents at least fifty percent of the largest linear dimension of the package the chip takes up more than twenty-five percent of the surface area of the package.

26. The electronic device of claim 19, wherein the largest linear dimension of the chip represents between fifty and seventy percent of the largest linear dimension of the package.

27. The electronic device of claim 19, wherein the surface area of the chip represents between twenty-five and fifty percent of the surface area of the package.

28. The electronic device of claim 19, wherein the chip and the package have rectangular surfaces, each edge of the chip representing between fifty and seventy percent of the edge of the package to which it is parallel.

29. A method of making an electronic device, the method comprising:
encapsulating a semiconductor chip in a package with flush contacts having the chip encapsulated therein, wherein the chip takes up more than twenty-five percent of the surface area of the package; and
subjecting the encapsulated chip to at least 2500 temperature cycles between temperatures of −40° C. to +125° C.

30. The method of claim 29, wherein the semiconductor chip has a thickness smaller than 160 μm.

31. The method of claim 29, wherein at least one of the following relationships exists between the chip and the package:
the largest linear dimension of the chip represents at least fifty percent of the largest linear dimension of the package; or
the surface area of the chip represents between twenty-five and fifty percent of the surface area of the package; or
the chip and the package having rectangular major surfaces, each edge of the chip represents between fifty and seventy percent of the edge of the package to which it is parallel.
